(19) United States
(12) Patent Application Publication
(10) Pub. No.: US 2025/0069869 A1
(43) Pub. Date: Feb. 27, 2025

(54) PLASMA ANALYZER, PLASMA PROCESSING APPARATUS, AND MANUFACTURING METHOD OF SEMICONDUCTOR DEVICE USING THE SAME

(71) Applicant: SAMSUNG ELECTRONICS CO., LTD., Suwon-si (KR)

(72) Inventors: Jonghwa LEE, Suwon-si (KR); Jawon KO, Suwon-si (KR); Taijo JEON, Suwon-si (KR); Yunsong JEONG, Suwon-si (KR)

(73) Assignee: SAMSUNG ELECTRONICS CO., LTD., Suwon-si (KR)

(21) Appl. No.: 18/636,962

(22) Filed: Apr. 16, 2024

(30) Foreign Application Priority Data
Aug. 22, 2023 (KR) 10-2023-0110020

(51) Int. Cl. H01J 37/32

(52) U.S. Cl. CPC H01J 37/32917; H01J 37/3244; H01J 37/32642; H01J 2237/2007; H01J 2237/202; H01J 2237/2445

(57) ABSTRACT

A plasma processing apparatus includes a chamber in which plasma is generated, a support portion configured to support an object to be processed within the chamber, a head portion within the chamber and opposite to the support portion in a first direction, and a plasma analyzer including: a plurality of light collectors in the head portion, the plurality of light collectors configured to receive light emitted from plasma at a plurality of positions, a spectrometer outside the chamber nd connected to the plurality of light collectors, and a multiplexer connected between the plurality of light collectors and the spectrometer, the multiplexer configured to select one of a plurality of lights transmitted from the plurality of light collectors and transmit the selected one of the plurality of lights to the spectrometer.

### CROSS-REFERENCE TO RELATED APPLICATION

This application is based on and claims priority to Korean Patent Application No. 10-2023-0110020 filed on Aug. 22, 2023, in the Korean Intellectual Property Office, the disclosure of which is incorporated herein by reference in its entirety.

### BACKGROUND

### 1. Field

Example embodiments of the disclosure relate to a plasma analyzer, a plasma processing apparatus including the plasma analyzer, and a semiconductor device manufacturing method using the plasma processing apparatus.

### 2. Description of Related Art

A semiconductor device may be formed by various semiconductor manufacturing processes, including an etching process, a deposit process, an ashing process, and a cleaning process. A process using plasma may be applied to a semiconductor manufacturing process.

In a process using plasma, the characteristics of the plasma within the process chamber may be analyzed. In related art, in order to check for abnormalities in the process using plasma, an optical emission spectroscopy (OES), which analyzes light emitted through a view port provided at a point on a side of the process chamber, may be used. However, such a method is only a one-dimensional analysis of the emission spectrum and is mainly used only for an end point detection (EPD) purpose.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a plasma analyzer that may effectively detect the characteristics of plasma within a plasma process chamber.

One or more example embodiments further provide a plasma processing apparatus that may effectively detect the characteristics of the plasma within the plasma process chamber and actively control the plasma density through the detected plasma characteristics.

One or more example embodiments further sill provide a method for manufacturing a semiconductor device using a plasma analyzer that may effectively detect the characteristics of plasma in the plasma process chamber and a plasma processing apparatus using the same.

Additional aspects will be set forth in part in the description which follows and, in part, will be apparent from the description, or may be learned by practice of the presented embodiments.

According to an aspect of an example embodiment, a plasma processing apparatus may include a chamber in which plasma is generated, a support portion configured to support an object to be processed within the chamber, a head portion within the chamber and opposite to the support portion in a first direction, and a plasma analyzer including a plurality of light collectors in the head portion, the plurality of light collectors configured to receive light emitted from plasma at a plurality of positions, a spectrometer outside the chamber and connected to the plurality of light collectors, and a multiplexer connected between the plurality of light collectors and the spectrometer, the multiplexer configured to select one of a plurality of lights transmitted from the plurality of light collectors and transmit the selected one of the plurality of lights to the spectrometer.

According to an aspect of an example embodiment, a plasma processing apparatus may include a chamber in which plasma is generated, a support portion configured to support an object to be processed within the chamber, a head portion within the chamber and opposite to the support portion in a first direction, and a plasma analyzer including: a plurality of light collectors configured to receive light emitted from the plasma at a plurality of positions of the head portion, a multiplexer connected to the plurality of light collectors and configured to select one of a plurality of lights transmitted from the plurality of light collectors, and a spectrometer connected to the multiplexer and configured to analyze light, and wherein the multiplexer comprises a tiltable mirror, the tiltable mirror is configured to be iteratively tilted at a predetermined angle and at a predetermined frequency, and the tiltable mirror is configured to reflect the plurality of lights and to sequentially provide the plurality of lights to the spectrometer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a diagram illustrating a plasma processing apparatus according to one or more example embodiments;

FIG. 2 is a diagram illustrating a plasma analyzer according to one or more example embodiments;

FIG. 3 is a diagram illustrating a portion of a plasma analyzer according to one or more example embodiments;

FIG. 4 is an enlarged view of the portion R of FIG. 2 according to one or more example embodiments;

FIG. 5 is an enlarged view of the portion R of FIG. 2 according to some embodiments according to one or more example embodiments;

FIG. 6 is a diagram illustrating a multiplexer of a plasma analyzer according to one or more example embodiments;

FIG. 7 is a diagram illustrating a spectrometer of a plasma analyzer according to one or more example embodiments;

FIGS. 8 to 10 are diagrams illustrating analysis of plasma density through a plasma analyzer according to one or more example embodiments;

FIGS. 11 to 14 are diagrams illustrating control of a plasma processing apparatus according to one or more example embodiments; and

FIG. 15 is a flowchart of a manufacturing method of a semiconductor device, according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In order to clearly describe the present disclosure in the drawing, components not related to the description may be omitted, and identical or similar constituent elements may be given the same reference number.

In addition, the size and thickness of each component shown in the drawings are arbitrarily indicated for convenience of description and thus the present disclosure is not necessarily limited to what is shown.

When it is described that an element is “coupled” to another element, the description may include not only a “directly” connection, but also an “indirect” connection between other members. In addition, unless explicitly described to the contrary, the word “comprise”, and variations such as “comprises” or “comprising”, will be understood to imply the inclusion of stated elements but not the exclusion of any other elements.

It will be understood that when an element such as a layer, film, region, or substrate is referred to as being “on” another element, the element may be directly on the other element or intervening elements may also be present. In contrast, when an element is referred to as being “directly on” another element, there may be no intervening elements present. Further, when an element is “on” a reference portion, the element may be located above or below the reference portion, and this does not necessarily indicate that the element is located “on” in a direction opposite to gravity.

Further, throughout the specification, reference to “planar” may indicate a case where a target component is viewed from above, and reference to “in a cross-section” may indicate a case where a cross-section obtained by cutting the target component and viewing the target component from the side.

Hereinafter, referring to the accompanying drawings, a plasma processing apparatus according to some embodiments will be described.

In the present specification, “plasma process” may indicate that a specific treatment is performed on a substrate (e.g., a wafer), which may be an object to be processed, using plasma. For example, the plasma process may include all processes using plasma in the semiconductor manufacturing process, such as a deposit process, a cleaning process, an ashing process, and an etching process. The following description mainly focuses on an etching process among the plasma processes for convenience of understanding. However, the following description is not limited to the etching process and may also be applied to other plasma processes other than the etching process.

As described herein, the same reference number may be used to include a singular component or a group of multiple of components. For example, a through-hole and a plurality of through-holes may be indicated with the same reference number (e.g., 17).

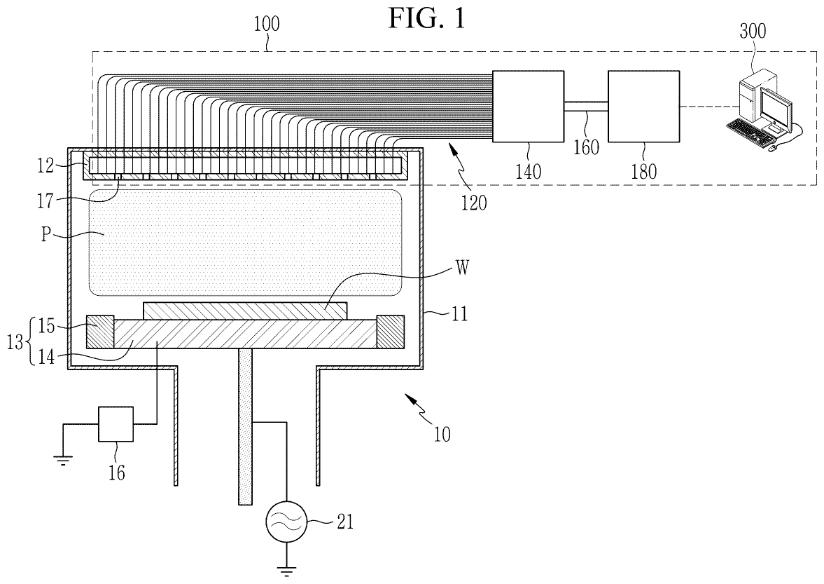

FIG. 1 is a diagram illustrating a plasma processing apparatus according to one or more example embodiments. In FIG. 1, the plasma processing apparatus 10 is illustrated in a cross-sectional view.

A plasma processing apparatus 10 according to some embodiments may be a device for etching an etching target film on a wafer W placed in a chamber 11. The plasma processing apparatus 10 is not limited to an etching device, and may also be a deposit device, an ashing device, and a cleaning device.

Plasma P generated in the plasma processing apparatus 10 according to some embodiments may be capacitively coupled plasma (CCP), but is not limited thereto, and may be inductively coupled plasma (ICP) or microwave plasma.

Referring to FIG. 1, the plasma processing apparatus 10 according to some embodiments may include a chamber 11, a support portion 13, a head portion 12, and a plasma analyzer 100.

The chamber 11 may provide an internal space where a plasma treatment process for an object to be processed is performed. Hereinafter, a wafer W is exemplified as the object to be processed, but other objects to be processed may be implemented as will be understood by one of ordinary skill in the art from the disclosure herein. In the internal space, plasma P may be generated such that the plasma process for the wafer W may be performed. The chamber 11 may closed and sealed from the outside such that a vacuum state may be maintained. A sidewall of the chamber 11 may be provided with a gate for the entry and exit of the wafer W.

The chamber 11 may be connected to a discharge line to discharge gas on one lower side, and the discharge line may be connected to a vacuum pump. The chamber 11 may have a cylindrical shape, but the shape is not limited thereto. The chamber 11 may include at least one of a metal and an insulator.

The support portion 13 may be disposed in the chamber 11 and may support the wafer W to be processed with the plasma P. The support portion 13 may be disposed in a lower portion of an internal space of the chamber 11. The support portion 13 may have a disk shape with a larger diameter than the wafer W to be supported on the support portion 13, but is not limited thereto.

According to some embodiments, the support portion 13 may be driven in a vertical direction (a direction vertical relative to a head portion, hereinafter referred to as a first direction). Referring to FIG. 1, the support portion 13 may be connected to the driving portion 16, and may be moved in the first direction by the driving portion 16. Accordingly, the wafer W supported on the support portion 13 may be brought closer to or farther away from the head portion 12.

Referring to FIG. 1, the support portion 13 may include a chuck 14 and an edge ring 15. The chuck 14 may fix the wafer W, and for example, the chuck 14 may include an electrostatic chuck that fixes the wafer W with electrostatic force. The edge ring 15 may control the plasma P and may be arranged to surround the outside of the chuck 14. The aforementioned chuck 14 and the edge ring 15 may be individually driven in the first direction by the driving portion 16. According to some embodiments, plasma density may be adjusted through the operation of the chuck 14 and the edge ring 15.

According to some embodiments, the chuck 14 may include a heater for heating a supported object. For example, when a plasma process is performed within a chamber 11 with the wafer W supported on an upper portion of the chuck 14, the wafer W may be heated to a temperature suitable for the plasma process through a heater built into chuck 14. A temperature of the chuck 14 may be controlled differently depending on a partitioned region, and the plasma density in the upper portion of the chuck 14 may vary depending on the controlled temperature.

According to some embodiments, a power source 21 may be connected to the support portion 13. For example, the power source 21 may be a radio frequency (RF) power source for generating and controlling the plasma P. Accordingly, the RF power for generating plasma may be supplied to the support portion 13 from the power source 21. Accordingly, the support portion 13 may be a lower electrode generating plasma. In this case, a lower electrode corresponding to the lower electrode may be the head portion 12. Accordingly, plasma P is generated in a space between the head portion 12, which is the upper electrode, and the support portion 13, which is the lower electrode, and the wafer W positioned between the head portion 12 and the support portion 13 may be processed by the generated plasma P.

The head portion 12 may be disposed within the chamber 11 and may be disposed opposite to the support portion 13 described above with the wafer W disposed therebetween. The head portion 12 may be disposed at an upper portion of an internal space of the chamber 11. The head portion 12 may have a disk shape, but is not limited thereto.

According to some embodiments, the head portion 12 may include a plurality of injection holes 17 that inject gas generating the plasma P into the internal space of the chamber 11. Gas generating the plasma P above the wafer W supported on the support portion 13 may be supplied through the plurality of injection holes 17. For example, referring to FIG. 1, the head portion 12 may have an empty interior, and the plurality of injection holes 17 may be provided on one side facing the support portion 13. The head portion 12 may be connected to a gas supply source to supply gas into the head portion 12.

According to some embodiments, the plurality of injection holes 17 may be partitioned into a plurality of regions, and the plurality of regions may individually control the amount of gas injection. Plasma density may vary depending on the injection amount of gas.

As described above, the head portion 12 may be the upper electrode for generating the plasma P. The power source 21 may be connected only to the support portion 13 and may not connected to the head portion 12, but the disclosure is not limited thereto, and the support portion 13 and the head portion 12 may be connected with individual power sources. Alternatively, the power source 21 may be connected only to the head portion 12 and not to the support portion 13.

The plasma processing apparatus 10 according to some embodiments may include a plasma analyzer 100 connected to the head portion 12. According to some embodiments, the plasma analyzer 100 may analyze plasma by zone in real time within the chamber 11 of the plasma processing apparatus 10. Hereinafter, the plasma analyzer 100 according to some embodiments will be described in detail.

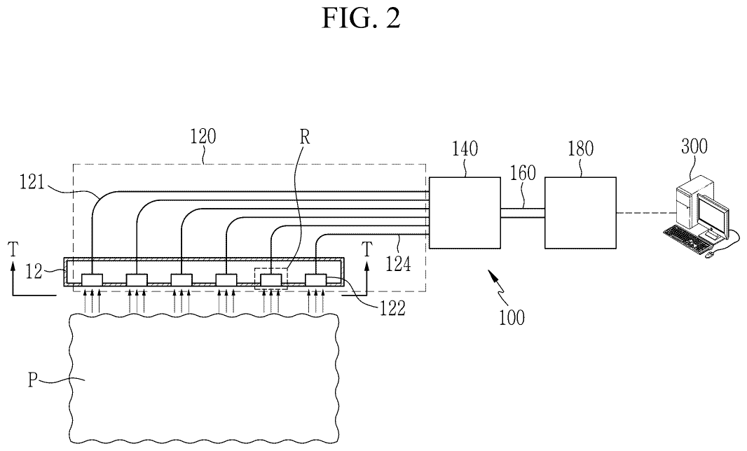

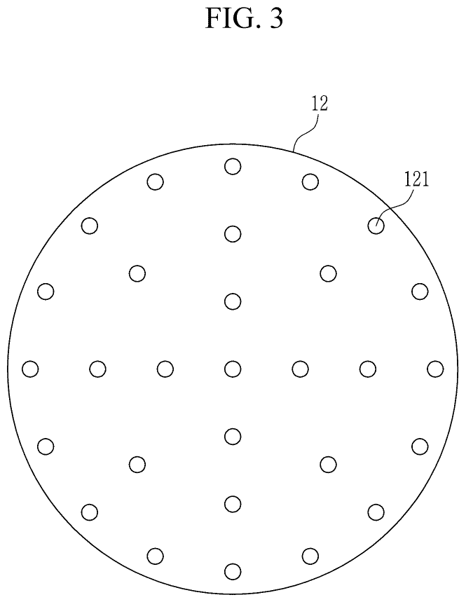

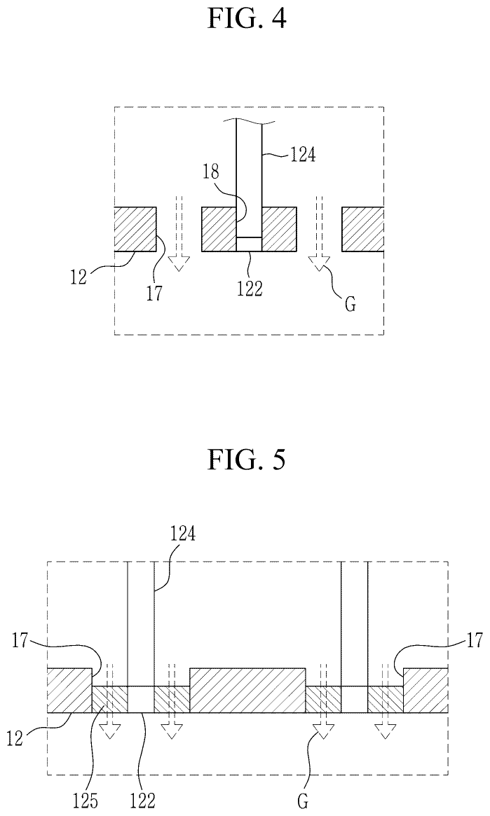

FIG. 2 is a diagram illustrating a plasma analyzer according to one or more example embodiments. FIG. 3 is a diagram illustrating a portion of a plasma analyzer according to one or more example embodiments. FIG. 4 is an enlarged view of the portion R of FIG. 2 according to one or more example embodiments. FIG. 5 is an enlarged view of the portion R of FIG. 2 according to some embodiments according to one or more example embodiments.

In FIG. 2 to FIG. 5, for better comprehension, some aspects may be omitted, and some aspects are shown schematically by exaggeration or simplification. FIG. 2, FIG. 4, and FIG. 5 are cross-sectional views, and FIG. 3 is a view at the T-T direction in FIG. 2, with the injection hole omitted.

Referring to FIG. 1, the plasma analyzer 100 according to some embodiments may be connected to the head portion 12. Since the plasma analyzer 100 may be configured to analyze the light emitted from the plasma P, a component that collects the light may be placed in the head portion 12.

Referring to FIG. 2, the plasma analyzer 100 according to some embodiments may include a plurality of light collectors 120, a multiplexer 140, and a spectrometer 180. The plurality of light collectors 120 may include individual light collectors, such as light collector 121.

The plurality of light collectors 120 may be components that respectively receive light emitted from the plasma P at a plurality of locations in the chamber 11. According to some embodiments, the plurality of light collectors 120 may be arranged in the head portion 12 disposed opposite to the support portion 13 where the wafer W is supported.

Referring to FIG. 3, the plurality of light collectors 120 may be arranged spaced apart from each other on a plane. On a plane, the plurality of light collectors, such as light collector 121 may be arranged at plurality of positions spaced apart from each other.

According to some embodiments, the plurality of light collectors 120 each may receive light emitted from the plasma P in the chamber 11 and transmit the received light to a spectrometer 180 (or multiplexer 140) positioned outside the chamber 11. As the plurality of light collectors 120 are arranged at the plurality of positions spaced apart from each other on a plane, the density of plasma at the plurality of positions may be detected.

According to some embodiments, the plurality of light collectors 120 may be densely arranged from a center to an edge on the plane of the head portion 12. According to some embodiments, the plurality of light collectors 120 may be arranged radially on the plane of the head portion 12. According to some embodiments, the plurality of light collectors 120 may be arranged on a concentric circle centered on a central point on the plane of the head portion 12. According to some embodiments, the plurality of light collectors 120 may be arranged symmetrically about the center point on the plane of the head portion 12. The arrangement of the plurality of light collectors 120 is not limited to the above-described arrangement and may be arranged in various ways.

As the number of the plurality of light collectors 120 increases, the more light (light emitted from plasma) may be collected from more positions, ultimately allowing the plasma density to be detected from more positions. The plurality of light collectors 120 may all have the same configuration. Hereinafter, the configuration of each of the plurality of light collectors 120 will be described in detail.

Each light collector 120 may include a window 122 and an optical transmission member 124.

Since the window 122 is a portion through which the plasma P is exposed, the window 122 may be a portion where the light emitted from the plasma P is incident. The window 122 may include materials that are durable against vacuum, heat, electromagnetic waves, and the like.

The window 122 may be formed of a material that transmits light emitted from the plasma P. According to some embodiments, the window 122 may transmit light of all wavelength regions from the plasma P. For example, the window 122 may include a material through which light of 100 nm to 2000 nm in wavelength range is transmitted.

The window 122 may include at least one optical element for collecting and transmitting light.

According to some embodiments, one end of the window 122 may penetrate through the head portion 12 and be exposed toward the inside of the head portion 12. For example, one side of the window 122 may be exposed to the plasma P. Accordingly, light emitted from the plasma P may be incident through the window 122.

Referring to FIG. 4, the window 122 may be inserted into a through-hole 18 provided in the head portion 12. The through-hole 18 may be disposed between the plurality of injection holes 17 formed in the head portion 12 for gas injection. At least one through-hole 18 may be placed between two adjacent injection holes 17, however the position and dispersion of the through-holes (e.g., through-hole 18) is not limited thereto. A diameter of the through-hole 18 may be smaller than a diameter of the injection hole 17. The diameter of the through-hole 18 may be equal to or smaller than a diameter of the injection hole 17.

According to some embodiments, the window 122 may be disposed within one injection hole 17 of the plurality of injection holes 17, and may be supported within one injection hole 17 by the support member 125. Referring to FIG. 5, the window 122 may be placed within the injection hole 17. The window 122 may be supported in a fixed position within the injection hole 17 by the support member 125. The support member 125 may be configured not to block a space between the window 122 and the injection hole 17. Accordingly, gas G may be injected through the space between the window 122 and the injection hole 17. For example, the support member 125 may have a plurality of through-holes through which the gas G may pass.

As shown in FIG. 4, the window 122 maybe inserted into the through-hole 18, and as shown in FIG. 5, the window 122 may be fixed into the injection hole 17.

The window 122 may be connected to an optical transmission member 124. A separate connection member connecting the window 122 and the optical transmission member 124 may be further included.

The optical transmission member 124 may be a component that connects the window 122 and a multiplexer 140. The optical transmission member 124 may be connected to the window 122 and may transmit light incident through the window 122 to the multiplexer 140.

The optical transmission member 124 may be installed while penetrating the chamber 11. According to some embodiments, one side of the optical transmission member 124 may be disposed in the chamber 11 and connected with the window 122, and the other side may be disposed in the chamber 11 and connected to the multiplexer 140. Accordingly, each of the plurality of light collectors 120 may transmit light incident at the window 122 disposed in the chamber 11 to the multiplexer 140 disposed outside the chamber 11 through the optical transmission member 124.

The optical transmission member 124 may include an optical fiber. Accordingly, the plurality of light collectors 120 may include a plurality of optical fiber bundles, and the plurality of optical fiber bundles may extend from inside the chamber 11 to the outside of the chamber 11. However, the optical transmission member 124 is not limited to optical fibers, and may include other components that may transmit light, such as optical waveguides (or optical wave pipe) and optical elements.

All of the collected through the plurality of light collectors 120 may be transmitted to the multiplexer 140.

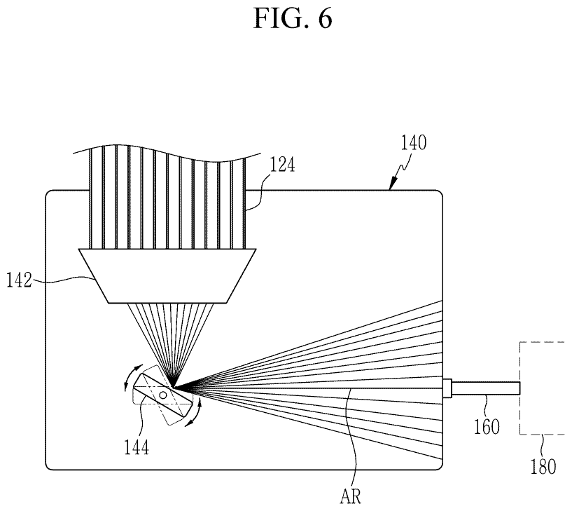

FIG. 6 is a diagram illustrating a multiplexer of a plasma analyzer according to one or more example embodiments.

The multiplexer 140 may be connected between the plurality of light collectors 120 and the spectrometer 180. The multiplexer 140 may select one of the plurality of lights transmitted from the plurality of light collectors 120 and transmit the selected light to the spectrometer 180. Since the optical transmission member 124 of the plurality of light collectors 120 extends from the interior of the chamber 11 toward the exterior of the chamber 11, the multiplexer 140 may be placed outside of the chamber 11.

Referring to FIG. 6, the multiplexer 140 may include a coupling element 142 and a mirror 144.

The coupling element 142 may be connected to ends of the plurality of optical transmission members 124 and may support the plurality of optical transmission members 124. In addition, the coupling element 142 may control an optical path such that paths of plurality of lights emitted from each of the plurality of optical transmission members 124 are directed to the mirror 144. For example, the coupling element 142 may include an optical element and may include a support component for supporting the plurality of optical transmission members 124.

The mirror 144 may reflect the plurality of lights transmitted from the plurality of optical transmission members 124 and may direct the light to be incident on the spectrometer 180.

According to some embodiments, the mirror 144 may be tiltable. Through this, one of the plurality of incident lights may be selected and transmitted to the spectrometer 180.

The mirror 144 may be tilted repeatedly at a predetermined angle and at a predetermined frequency. The plurality of lights transmitted from the plurality of optical transmission members 124 may each have a different angle of incidence incident on the mirror 144. One light among the plurality of lights may be transmitted to a target optical path by tilting the mirror 144 at a predetermined angle. In addition, the plurality of lights may be sequentially transmitted to a target optical path by iteratively tilting the mirror 144 at a predetermined frequency.

For example, as shown in FIG. 6, the multiplexer 140 may be formed to transmit only one optical path AR among the plurality of optical paths reflected from the mirror 144 to the spectrometer 180. Accordingly, the plurality of lights may be transmitted to the spectrometer 180 sequentially one by one by being reflected on the mirror 144 that is repeatedly tilted at a predetermined angle and at a predetermined frequency. Accordingly, the multiplexer 140 may divide optical information collected from each of the plurality of light collectors 120 into the plurality of light collectors 120 and transmit them to the spectrometer 180.

A collimator 160 may be placed between the multiplexer 140 and the spectrometer 180. The collimator 160 may collimate the light emitted from the multiplexer 140 such that the collimated light may be incident on the spectrometer 180.

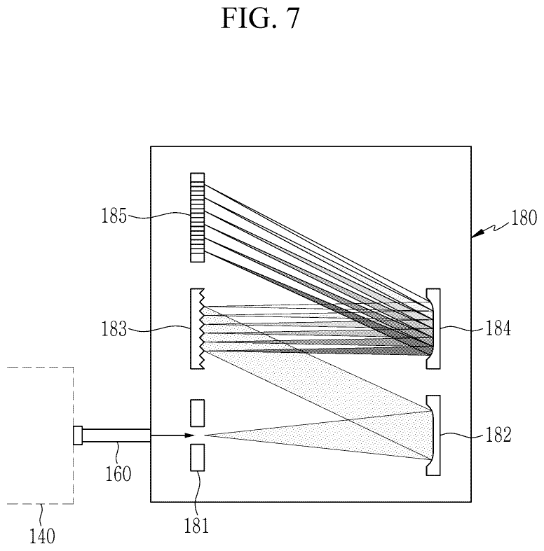

FIG. 7 is a diagram illustrating a spectrometer of a plasma analyzer according to one or more example embodiments.

The spectrometer 180 may analyze optical information received from the multiplexer 140. The spectrometer 180 may be placed outside the chamber 11 and may be connected to the plurality of light collectors 120 through the multiplexer 140.

Referring to FIG. 7, the spectrometer 180 may include an incident slit 181, a collimating mirror 182, a diffraction lattice 183, a collimating mirror 184, and a detection sensor 185.

The incident slit 181 may receive light, and may diffuse the incident light to the collimating mirror 182.

The collimating mirror 182 may reflect the diffused light into the diffraction lattice 183. The collimating mirror 182 may convert the light diffused by the incident slit 181 into parallel light and reflect the parallel light to the diffraction lattice 183.

The diffraction lattice 183 may separate light according to a wavelength. For example, the diffraction lattice 183 may separate wavelengths of the light spectrum through lattices that arrange a plurality of grooves or a plurality of protrusions on one side of the mirror.

The detection sensor 185 may detect each light separated by wavelength. For example, the detection sensor 185 may be an array-type sensor. For example, the detection sensor 185 may include a sensor that converts an optical signal into an electronic signal. For example, the detection sensor 185 may include a charged coupled device (CCD).

As described, the plurality of lights collected from the plurality of light collectors 120 disposed at each of the plurality of positions in the chamber 11 may sequentially enter the spectrometer 180 through the multiplexer 140 and be analyzed. Additionally, the spectrometer 180 may analyze sequentially incident light by wavelength. Therefore, the light of the plasma in the chamber 11 may be analyzed for each position through the plasma analyzer 100 according to some embodiments.

Referring to FIG. 1, the plasma analyzer 100 according to some embodiments may include a monitoring device 300.

The monitoring device 300 may monitor the plasma detection information in the chamber 11 in real time. The monitoring device 300 may be connected with the spectrometer 180 and receive light analysis information in the chamber 11 from the spectrometer 180. Information may be transmitted and received between the monitoring device 300 and the spectrometer 180 through wired or wireless communication.

The monitoring device 300 may map the plasma detection information in the chamber 11 in real time while the plasma process is in progress in the plasma processing apparatus 10.

For example, the light emitted from the plasma P may be collected for each of the plurality of positions through the windows 122 placed at the plurality of positions in the chamber 11, and the light information detected through the spectrometer 180 may be analyzed in the monitoring device 300. For example, during light analysis in the monitoring device 300, the plasma density inside the chamber 11 may be mapped by calculating the data received from the spectrometer 180 using software.

More specifically, each light collector of the plurality of light collectors 120 may detect a spectrum of plasma incident on a point corresponding to the light collector 120 position, and analyze a state of the plasma using detection information.

The plasma analyzer 100 according to some embodiments may detect spectrums of plasma at the plurality of points, as the plurality of light collectors 120 are dispersed at a plurality of positions corresponding to the plurality of points. Thus, the density of plasma may be checked depending on the position, thereby detecting points where the density of plasma is relatively high or low. Using the detection information, the plasma processing apparatus 10 according to some embodiments may be actively controlled such that the density of plasma P may be uniformly distributed within the chamber 11, or the density of plasma P may be adjusted according to position.

Hereinafter, analysis of plasma density using the plasma analyzer 100 provided in the plasma processing apparatus 10 according to some embodiments will be described.

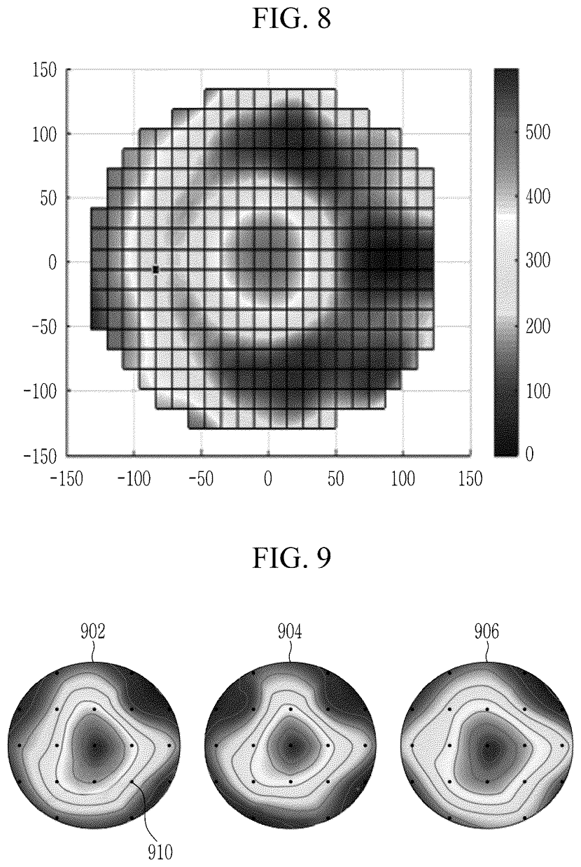

FIGS. 8 to 10 are diagrams illustrating analysis of plasma density through a plasma analyzer according to one or more example embodiments.

FIG. 8 shows mapping of the plasma density on the head portion 12 on a two-dimensional plan view. The mapping may be performed using spectrum information detected by each of the plurality of light collectors 120 of the plasma analyzer 100 when the plasma process is in progress with respect to the water W in the chamber 11 using the plasma processing apparatus 10. In FIG. 8, the coordinate axes on the left and bottom each show the positions, and the coordinate axis on the right is an example showing the density of plasma in color and relative numbers. In FIG. 8, the circular shape shown on the coordinate axis is a planar mapping of the plasma density according to the position on the head portion 12 where the plurality of light collectors 120 are placed.

Referring to FIG. 8, the plasma density is high in the center and left edge of the head portion 12 on a plan view. Therefore, the plasma density appears uniform by controlling the plasma processing apparatus 10, thereby improving the plasma process.

Information detected through a spectrometer 180 for light collected from the plurality of light collectors 120 may be communicated to the monitoring device 300, and thus the monitoring device 300 may monitor the plasma density within the plasma processing apparatus 10 in real time. For example, when performing a plasma process for the wafer W with the plasma processing apparatus 10, the plasma processing apparatus 10 may be controlled to make the plasma density uniform, while monitoring the plasma density according to the position within the chamber 11 in real time using information detected by the plasma analyzer 100.

FIG. 9 shows changes over time in the plasma density analyzed through the plasma analyzer 100 and mapped into a two-dimensional plan view. The image 902 corresponds to a first time point, the image 904 corresponds to a second time point after the first time point, and the image 906 corresponds to a third time point after the second time point. The black dots, such as dot 910, in the images 902-906 in FIG. 9 indicate points corresponding to positions of the plurality of light collectors 120.

Referring to FIG. 9, the plasma density analyzed through the plasma analyzer 100 is changing from the image 902 to image 906. Thus, when the plasma processing apparatus 10 performs the plasma process on the wafer W, the plasma processing apparatus 10 may be controlled such that the plasma density analyzed in real time through the plasma analyzer 100 appears uniform, thereby improving the plasma process for the wafer W.

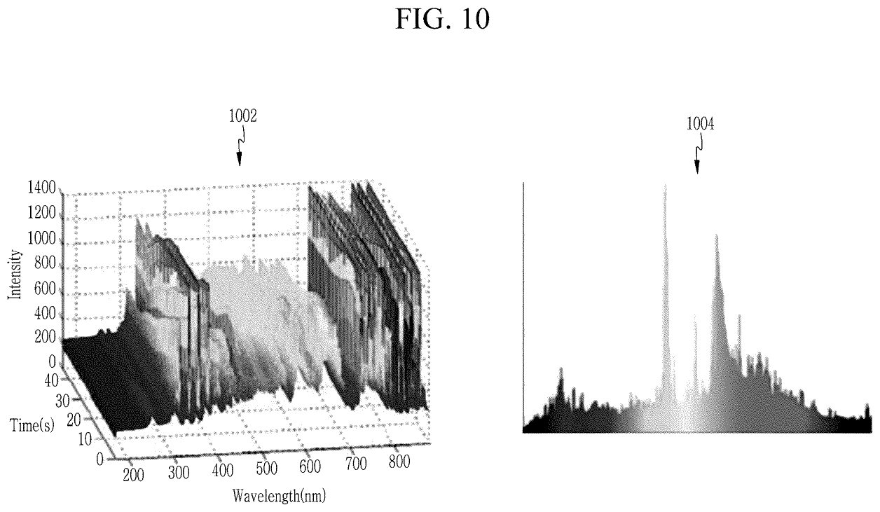

FIG. 10 shows a mapping of plasma density (intensity) at one point in the chamber 11 using spectrum information detected in one light collector 120 disposed at a position in the plasma analyzer 100 corresponding to the one point. That is, in FIG. 10 shows a mapping of the plasma density using the spectrum information detected at one point among the plurality of points marked by the black dots (e.g., dot 910) in FIG. 9. Graph 1002 in FIG. 10 shows plasma density (intensity) mapped in three dimensions according to wavelength and time. That is, the results of 3D-OES (time, wavelength, intensity) may be detected using the plasma analyzer 100 according to embodiments. Graph 1004 in FIG. 10 shows plasma density (intensity) mapped in two dimensions according to wavelength.

Referring to graph 1002 in FIG. 10, in one light collector 120 of the plasma analyzer 100, the density of plasma is high in the 350 nm to 450 nm and 750 nm to 900 nm wavelength ranges. Therefore, the plasma process for the wafer W may be improved by controlling the injection amount of the gas component representing a specific wavelength range among the gas injected in the plasma processing apparatus 10.

Specifically, the plasma process for the wafer W may be improved by using the plasma processing apparatus 10 equipped with the plasma analyzer 100 according to some embodiments.

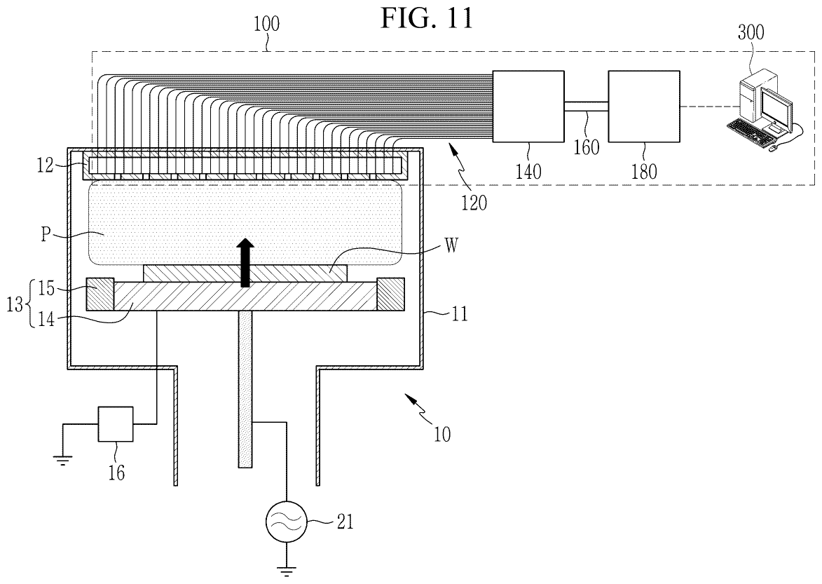

FIGS. 11 to 14 are diagrams illustrating control of a plasma processing apparatus according to one or more example embodiments.

Referring to FIG. 11, the plasma density may be adjusted by moving the chuck 14, which supports the wafer W, in the first direction (i.e., a direction closer to or farther away from the head portion 12). For example, when a space where the plasma P is generated becomes smaller by moving the chuck 14 in the direction closer to the head portion 12, the density of plasma P may increase.

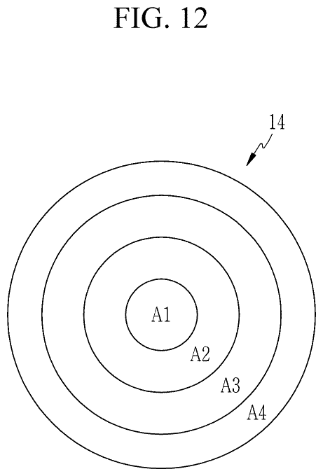

FIG. 12 is a top plan view of the chuck 14, and according to some embodiments. The chuck 14 may be divided into a plurality of areas A1 to A4 on the plane, and a temperature of each of the plurality of areas A1 to A4 may be adjusted individually. Accordingly, the plasma density may be adjusted by controlling the temperature of the chuck 14. For example, among the plurality of areas A1 to A4 in the chuck 14, the density of plasma P may be low in an area with a high temperature. In FIG. 12, the chuck 14 is partitioned into four areas, but the chuck 14 is not limited thereto, and the chuck 14 may be partitioned into much smaller or much more areas.

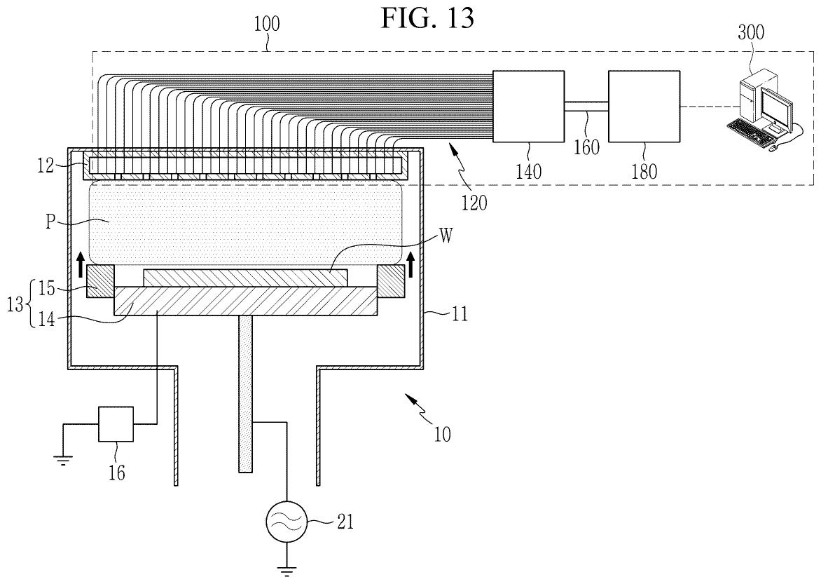

Referring to FIG. 13, the plasma density may be adjusted by moving the edge ring 15 surrounding the outside of the chuck 14 in the first direction. The driving portion 16 connected to the support portion 13 may simultaneously or individually drive the chuck 14 and the edge ring 15. For example, when the edge ring 15 is moved close to the head portion 12, density of plasma P at an edge of an object to be processed may decrease.

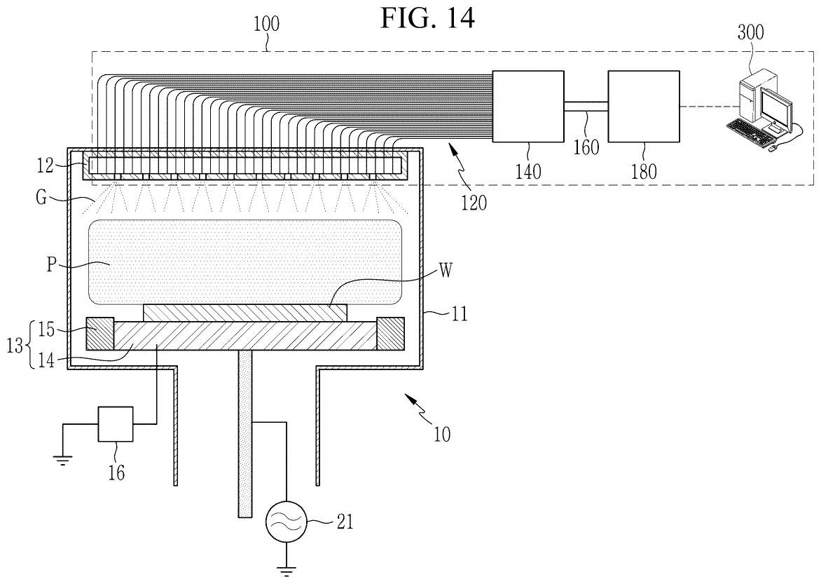

Referring to FIG. 14, plasma density may be adjusted by controlling the injection amount of gas injected into the chamber 11 through the head portion 12. The head portion 12 may include a plurality of injection holes 17 for injecting gas that generates the plasma P into the chamber 11. According to some embodiments, the plurality of injection holes 17 may be divided into a plurality of regions on a plane, and the plurality of regions each may individually control the gas injection amount. Therefore, the plasma density may be controlled by adjusting the amount of gas injection for each region. For example, the density of the plasma P may increase in a region with a large amount of gas injection.

The plasma density control method described with reference to FIG. 11 to FIG. 14 is provided as an example and is not exclusive. The plasma density control method may vary depending on the type or structure of the plasma processing apparatus.

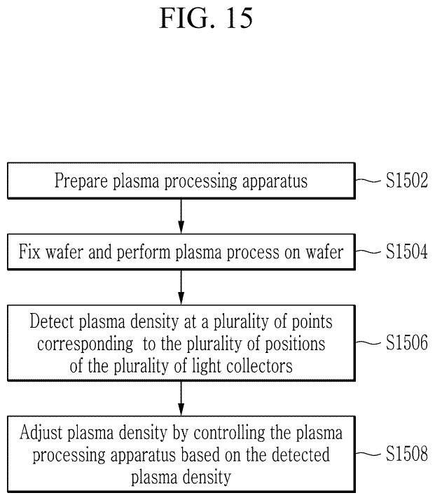

FIG. 15 is a flowchart of a manufacturing method of a semiconductor device, according to one or more example embodiments. Hereinafter, a manufacturing method of a semiconductor device according to some embodiments will be described with reference to FIGS. 1 and 15.

In operation S1502, the plasma processing apparatus 10 provided with the plasma analyzer 100 according to some embodiments may be prepared. The plurality of light collectors 120 of the plasma analyzer 100 may be arranged in a plurality of positions of the head portion 12 that is disposed facing the chuck 14 in the chamber 11.

In operation S1504, the wafer W may be fixed on the chuck 14 and the plasma processing apparatus 10 may be operated to perform a plasma process on the wafer W. In this case, gas generating plasma in the head portion 12 may be injected into the chamber 11 through the injection hole 17. The chuck 14 and the head portion 12 may respectively correspond to the lower electrode and the upper electrode, and the plasma P may be generated between the chuck 14 and the head portion 12.

In operation S1506, during the plasma process, the plasma density at the plurality of points corresponding to the plurality of positions of the plurality of light collectors 120 may be detected. According to some embodiments, a plurality of lights transmitted from the plurality of light collectors 120 may be sequentially transmitted one by one to the spectrometer 180 through the multiplexer 140. According to some embodiments, in the monitoring device 300 outside the chamber 11, plasma density information at the plurality of points corresponding to the positions of the plurality of light collectors 120 may be mapped in real time by receiving light detection information from the spectrometer 180.

In operation S1508, the detected (or mapped) plasma density may be checked, and the plasma density at the plurality of points corresponding to positions of the plurality of light collectors 120 may be adjusted by controlling the plasma processing apparatus 10 based on the detected (or mapped) plasma. In this case, the plasma processing apparatus 10 may be simultaneously controlled or substantially simultaneously controlled while monitoring the plasma density at the plurality of points in real time.

Thus, when a serious abnormality that is difficult to control is found while monitoring the detected plasma density, the plasma processing apparatus 10 may be stopped.

Furthermore, in the adjusting the plasma density according to the manufacturing method of the above-described semiconductor device, the plasma density may be adjusted by controlling at least one of a gap between the chuck 14 and the head portion 12 where the plasma P is generated, a temperature of the chuck 14, a position of the edge ring 15 surrounding the chuck 14, and an injection amount of gas injected from the head portion 12.

According to some embodiments, a plasma processing apparatus may include a plurality of light collectors arranged in the head portion of the chamber and each receives light emitted from the plasma at a plurality of positions, and thus the plasma density may be detected at each of the plurality of light collectors. In addition, the plasma density at the plurality of points may be monitored in real time through the plurality of light collectors. In addition, the plasma process may be improved by controlling the plasma processing apparatus using plasma density information detected in real time.

At least one of the devices, units, components, modules, units, or the like represented by a block or an equivalent indication in the above embodiments including, but not limited to, FIGS. 1-2, 6-7 and 11-15 may be physically implemented by analog and/or digital circuits including one or more of a logic gate, an integrated circuit, a microprocessor, a microcontroller, a memory circuit, a passive electronic component, an active electronic component, an optical component, and the like, and may also be implemented by or driven by software and/or firmware (configured to perform the functions or operations described herein).

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A plasma processing apparatus, comprising:
a chamber in which plasma is generated;
a support portion configured to support an object to be processed within the chamber;
a head portion within the chamber and opposite to the support portion in a first direction; and
a plasma analyzer comprising:
a plurality of light collectors in the head portion, the plurality of light collectors configured to receive light emitted from plasma at a plurality of positions;
a spectrometer outside the chamber and connected to the plurality of light collectors; and
a multiplexer connected to the plurality of light collectors and the spectrometer, the multiplexer configured to:
select one of a plurality of lights transmitted from the plurality of light collectors; and
transmit the selected one of the plurality of lights to the spectrometer.

2. The plasma processing apparatus of claim 1, wherein the multiplexer comprises a tiltable mirror, and
wherein the tiltable mirror is configured to reflect the plurality of lights transmitted to the multiplexer from the plurality of light collectors and to sequentially provide the plurality of lights to the spectrometer.

3. The plasma processing apparatus of claim 2, wherein the tiltable mirror is configured to be iteratively tilted at a predetermined angle and at a predetermined frequency.

4. The plasma processing apparatus of claim 1, wherein each of the plurality of light collectors comprises:
a window through which light is transmitted; and
an optical transmission member that penetrates the chamber of the plasma processing apparatus and is connected to the window and the multiplexer.

5. The plasma processing apparatus of claim 4, wherein the window is in a through-hole between at least two injection holes of a plurality of injection holes of the head portion of the plasma processing apparatus.

6. The plasma processing apparatus of claim 4, wherein the window is in one injection hole of a plurality of injection holes of the head portion of the plasma processing apparatus, and
wherein the window is supported by the one injection hole by a support member.

7. The plasma processing apparatus of claim 4, wherein the window is configured to transmit light in a wavelength range of about 100 nm to about 2000 nm.

8. The plasma processing apparatus of claim 1, wherein the spectrometer comprises an incident slit, a collimating mirror, a diffraction lattice, and a detection sensor.

9. The plasma processing apparatus of claim 1, wherein the plasma analyzer further comprises: a collimator between the multiplexer and the spectrometer and configured to collimate light.

10. The plasma processing apparatus of claim 1, wherein the plasma analyzer further comprises: a monitoring device connected to the spectrometer and configured to map plasma detection information at a plurality of points corresponding to the plurality of positions of the plurality of light collectors in real time.

11. The plasma processing apparatus of claim 1, wherein the plurality of light collectors are densely arranged from a center to an edge on a plane of the head portion.

12. The plasma processing apparatus of claim 1, wherein the plurality of light collectors are radially arranged on a plane of the head portion.

13. The plasma processing apparatus of claim 1, wherein the support portion comprises a chuck configured to fix the object to be processed, and
wherein the chuck is configured to be movable in the first direction.

14. The plasma processing apparatus of claim 13, wherein the support portion further comprises an edge ring at least partially surrounding an outside of the chuck and configured to be movable in the first direction.

15. The plasma processing apparatus of claim 13, wherein the chuck comprises a plurality of areas, and
wherein a temperature of each of the plurality of areas is individually controllable.

16. The plasma processing apparatus of claim 1, wherein the head portion comprises a plurality of injection holes through which gas generating the plasma is injected into the chamber.

17. The plasma processing apparatus of claim 16, wherein the plurality of injection holes are partitioned into plurality of areas, and
wherein the plurality of areas are configured to individually control a gas injection amount.

18. The plasma processing apparatus of claim 1, wherein the plurality of light collectors are arranged on concentric circles centered on a central point on a plane of the head portion.

19. The plasma processing apparatus of claim 1, wherein the plurality of light collectors are arranged symmetrically about a central point on a plane of the head portion.

20. A plasma processing apparatus, comprising:
a chamber in which plasma is generated;
a support portion configured to support an object to be processed within the chamber;
a head portion within the chamber and opposite to the support portion in a first direction; and
a plasma analyzer comprising:
a plurality of light collectors configured to receive light emitted from the plasma at a plurality of positions of the head portion;
a multiplexer connected to the plurality of light collectors and configured to select one of a plurality of lights transmitted from the plurality of light collectors; and
a spectrometer connected to the multiplexer and configured to analyze light, and
wherein the multiplexer comprises a tiltable mirror,
the tiltable mirror is configured to be iteratively tilted at a predetermined angle and at a predetermined frequency, and
the tiltable mirror is configured to reflect the plurality of lights and to sequentially provide the plurality of lights to the spectrometer.
